(19) United States
(12) Patent Application Publication
(10) Pub. No.: US 2011/0012177 A1
(43) Pub. Date: Jan. 20, 2011

(54) Nanostructure For Changing Electric Mobility

(75) Inventors: Dureseti Chidambarrao, Weston, CT (US); Oki Gunawan, Fair Lawn, NJ (US); Xiao Hu Liu, Briarcliff Manor, NY (US); Amlan Majumdar, White Plains, NY (US); Lidija Sekaric, Mount Kisco, NY (US); Jeffrey W. Sleight, Ridgefield, CT (US)

Correspondence Address: HARRINGTON & SMITH, 4 RESEARCH DRIVE, Suite 202, SHELTON, CT, 06484-6212, US

(73) Assignee: International Business Machines Corporation

(21) Appl. No.: 12/505,603

(22) Filed: Jul. 20, 2009

(51) Int. Cl. H01L 29/775; H01L 21/335

(52) U.S. Cl. 257/288; 438/197; 977/762; 257/E29.245; 257/E21.404; 257/14; 257/192

(57) ABSTRACT

A structure and a method for a semiconductor including a nanostructure semiconductor channel. The semiconductor may include a dielectric and an electrode, the electrode attached to the dielectric, a semiconductor channel may be disposed proximate to the dielectric, wherein the semiconductor channel has an electric mobility and is configured to have at least one dimension, and wherein the dielectric may be configured to apply a force at the at least one dimension.

### CROSS REFERENCE TO RELATED APPLICATION:

This application includes subject matter related to US Patent Application Serial No. (IBM docket YOR920080432US1) filed the same day as this application. The contents of that related application are hereby incorporated by reference in its entirety.

### BACKGROUND

1. Field

The present invention relates to a semiconductor structure and more specifically to a semiconductor nanostructure configured to develop a force.

2. Description of Related Art

Typically, a field effect transistor (FET) includes a source, a drain, and a gate. Methods and structures exist in the art which are directed to attain ever smaller sizes of the FET. A channel connects the source and the drain. A conductivity of the channel is controlled by a gate voltage. Methods and structures exist in the art to manage the conductivity of the channel for a particular technical purpose.

### BRIEF SUMMARY

Embodiments of the present disclosure provide a structure and method for an improved electric mobility in a semiconductor nanostructure channel. The present disclosure teaches how to make a gate stack capable of subjecting a semiconductor nanostructure channel to a predetermined mechanical force.

Briefly described, in architecture, one embodiment of the structure, among others, can be implemented as follows.

A semiconductor may include a dielectric and an electrode attached to the dielectric, a semiconductor channel may be disposed proximate to the dielectric, wherein the semiconductor channel has an electric mobility and is configured to have at least one dimension, and wherein the dielectric is configured to apply a force at the at least one dimension.

The present disclosure can also be viewed as providing a method for making a semiconductor. The method may include providing an electrode, attaching the electrode to a dielectric, disposing a semiconductor channel proximate to the dielectric, wherein the semiconductor channel may have an electric mobility. The method may also include configuring the semiconductor channel to have at least one dimension wherein the dielectric may be configured to apply a force at the at least one dimension.

### BRIEF DESCRIPTION OF THE DRAWINGS

Many aspects of the disclosure can be better understood with reference to the following drawings. Components in the drawings are not necessarily to scale, emphasis instead being placed upon clearly illustrating principles of the present invention.

FIG. 1 is an embodiment of a structure of a semiconductor of the present disclosure.

FIG. 2 illustrates a portion of another embodiment of a semiconductor of the present disclosure.

FIG. 3 illustrates a portion of the semiconductor of FIG. 2.

FIG. 4 illustrates illustrates a transistor with current I flowing from source S to drain D.

FIG. 5 illustrates tensile strain along a face of the nanowire of FIG. 3.

FIG. 6 illustrates asymmetrical strain enhancements along a nanowire thickness.

FIG. 7 illustrates one case of the crystallographic directions in considering mobility change in top/bottom surfaces of the nanostructure.

FIG. 8 illustrates one case of the crystallographic directions in considering a mobility change in left/right surfaces of the nanostructure.

FIG. 9 illustrates an embodiment of a method of the present disclosure.

FIG. 10 illustrates another embodiment of a method of the present disclosure.

FIG. 11 illustrates a system including a computer program product having computer-executable instructions to implement the method of FIG. 10.

Table 1 lists piezoelectric coefficients in a nanostructure along given crystallographic directions.

### DETAILED DESCRIPTION

The present invention relates to a semiconductor structure and more specifically to a semiconductor nanostructure configured to develop a force. The present disclosure is directed to a nanostructure, however, a term “nanowire” may be used interchangeably to describe the nanostructure. The nanowire presented in the exemplary embodiments below has a geometry that is unique and that provides a particular advantage in exploiting gate stack stress as a mobility enhancer. The semiconductor structure may be made in an array of multiple semiconductor structures as appreciated by a person having ordinary skill in the art.

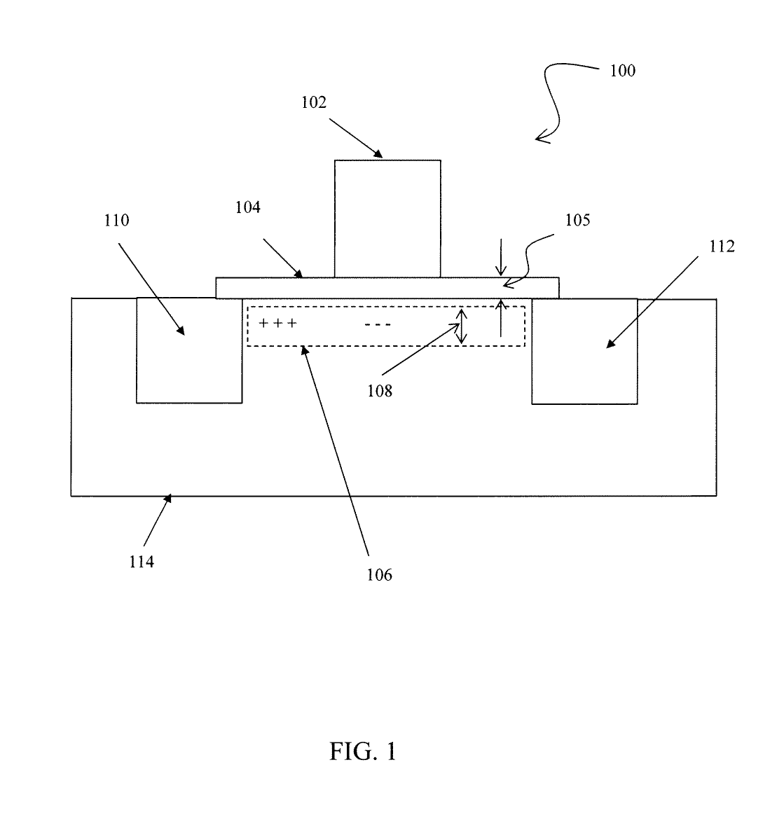

FIG. 1 is an embodiment of a structure of a semiconductor 100 of the present disclosure. The semiconductor 100 may include an electrode 102, the electrode 102 may be attached to a dielectric 104, a semiconductor channel 106 may be disposed proximate to the dielectric 104, the semiconductor channel 106 may have an electric mobility, as indicated by the “+” and “−” signs inside the semiconductor channel 106, and the semiconductor channel 106 may be configured to have at least one dimension 108 wherein the dielectric 104 may be configured to apply a force at the at least one dimension 108.

In the semiconductor 100, the electrode 102 may be a gate, such as a gate of an FET. In the semiconductor 100, the dielectric 104 may be a gate dielectric, such as a gate dielectric of the FET.

In the semiconductor 100, the semiconductor channel 106 may be at least one of a field effect transistor nanostructure n-channel and a field effect transistor nanostructure p-channel, depending of a preferred doping of the semiconductor channel 106, for example. As discussed below, the semiconductor channel 106 may be a nanostructure, such as a nanowire, having a cross-section of 20 nm×20 nm, or less.

In the semiconductor 100, the electric mobility may be one of an electron mobility and a hole mobility.

In the semiconductor 100, a thickness 105 of the dielectric 104 may be configured to change the electric mobility. Their stress and sign of stress may also be configured to change their electric mobility. When the field effect transistor nanostructure n-channel or the field effect transistor nanostructure p-channel may be made suitably thin, such as having the cross-section of 20 nm×20 nm or less a strain or a stress may impact the electron mobility or the hole mobility in the semiconductor channel 106. A ratio of the at least one dimension 108 to the thickness 105, such as a gate stack constituting the dielectric 104 and the electrode 102 representing a gate electrode, may be selected to enhance the electron mobility or the hole mobility in the semiconductor channel 106. The electron mobility or the hole mobility may be enhanced because a force, such as a strain or a stress, from the gate made of the electrode 102 may reach and influence the semiconductor channel 106. Any of the dimensions in the cross-section of 20 nm×20 nm or less may be at least one dimension 108.

In the semiconductor 100, the dielectric 104 may be configured to be compressive for a PFET (p-channel field effect transistor). Further, the dielectric 104 may be attached to a compressive gate coupled to the pFET.

In the semiconductor 100, the dielectric 104 may be configured to be tensile for an nFET (n-channel field effect transistor). Further, the dielectric 104 may be attached to a tensile gate coupled to the nFET.

In another embodiment of the present disclosure, a field effect transistor (FET) may include an electrode 102 attached to a gate of the FET, such as the electrode 102 being included in the gate, the electrode 102 may be attached to a dielectric 104, further including a semiconductor channel 106, wherein the semiconductor channel 106 may couple a source 110 and a drain 112, and the semiconductor channel 106 may have an electric mobility. The semiconductor channel 106 may be configured to have at least one dimension 108 wherein the dielectric 104 may be configured to apply a force at the at least one dimension 108.

In the FET, the dielectric 104 may be a gate dielectric. The semiconductor channel 106 may be at least one of a nanostructure n-channel and a nanostructure p-channel based on a predetermined doping.

In the FET, the electric mobility may be one of an electron mobility and a hole mobility. A thickness 105 of the dielectric 104 may be configured to change the electric mobility.

In the FET, the dielectric 104 may be configured to be compressive for a pFET and the dielectric 104 may be attached to a compressive gate coupled to the PFET. The dielectric 104 may be configured to be tensile for an nFET and the dielectric 104 may be attached to a tensile gate coupled to the nFET.

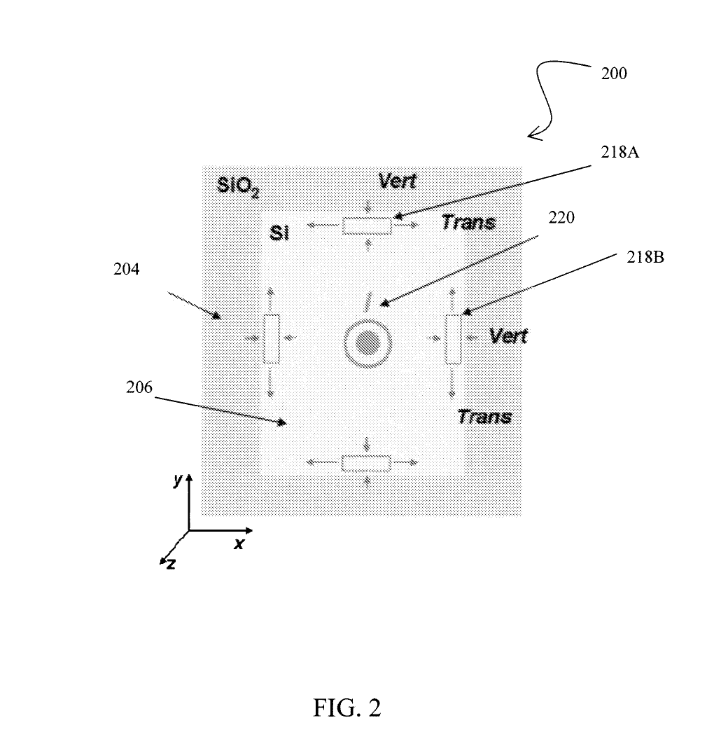

FIG. 2 illustrates a portion of another embodiment of a semiconductor 200 of the present disclosure. The semiconductor 200 is shown where a silicon 206 may be enclosed on four sides of the silicon 206 by an oxide (SiO₂) 204. The silicon 206 may correspond to the semiconductor channel 106 and the oxide 204 may correspond to the dielectric 104 shown in FIG. 1. As indicated by the three axes shown at the left bottom of FIG. 2, the semiconductor 200 may be in three dimensions. A current 1, shown as reference character 220, is also featured as flowing along the z axis. A set of arrows each, 218A and 218B, indicate a vertical and transverse direction of a force in a piece segment of the semiconductor, for illustration purposes in the case when the oxide 204 may cause a tensile strain normal to a path of the current 220. As an example, the silicon 206 may be subjected to a tensile strain from the four sides shown caused by the oxide 204, owing to the oxide 204 enclosing the silicon 206 from the four sides.

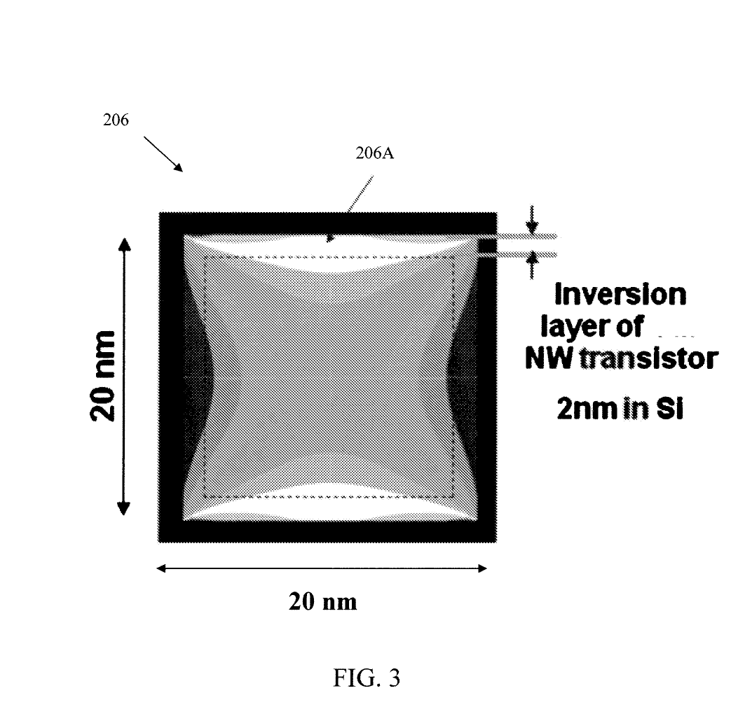

FIG. 3 illustrates a detail of the semiconductor 200 of FIG. 2. Here, the silicon 206 is shown. An exemplary dimension of the silicon 206 may be 20 nm×20 nm or less. An inversion layer 206A may be about 2 nm thick as shown and thus the stress from the gate dielectric and the gate electrode transfer efficiently into the inversion layer of the semiconductor (where the conduction is confined).

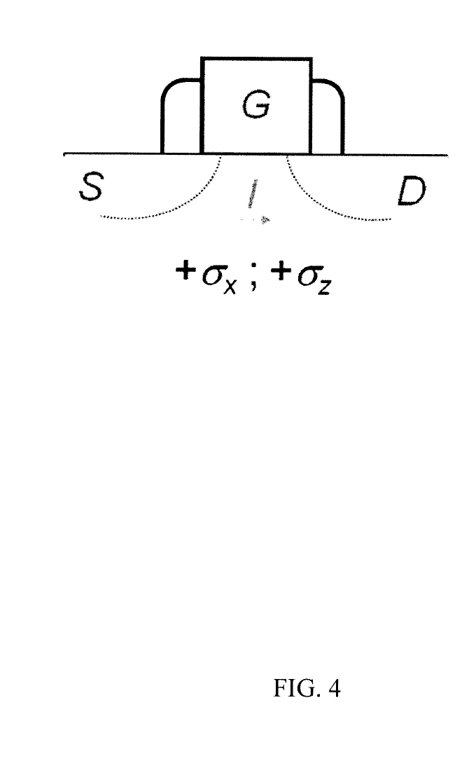

FIG. 4 illustrates a transistor such as the one illustrated at FIG. 1 with current I flowing from source S to drain D. The strain plot for the 20 nm×20 nm nanowire, similar to the one detailed at FIG. 3, illustrates graphically that the tensile strain caused by the presence of the oxide layer is normal to the direction of the current flow.

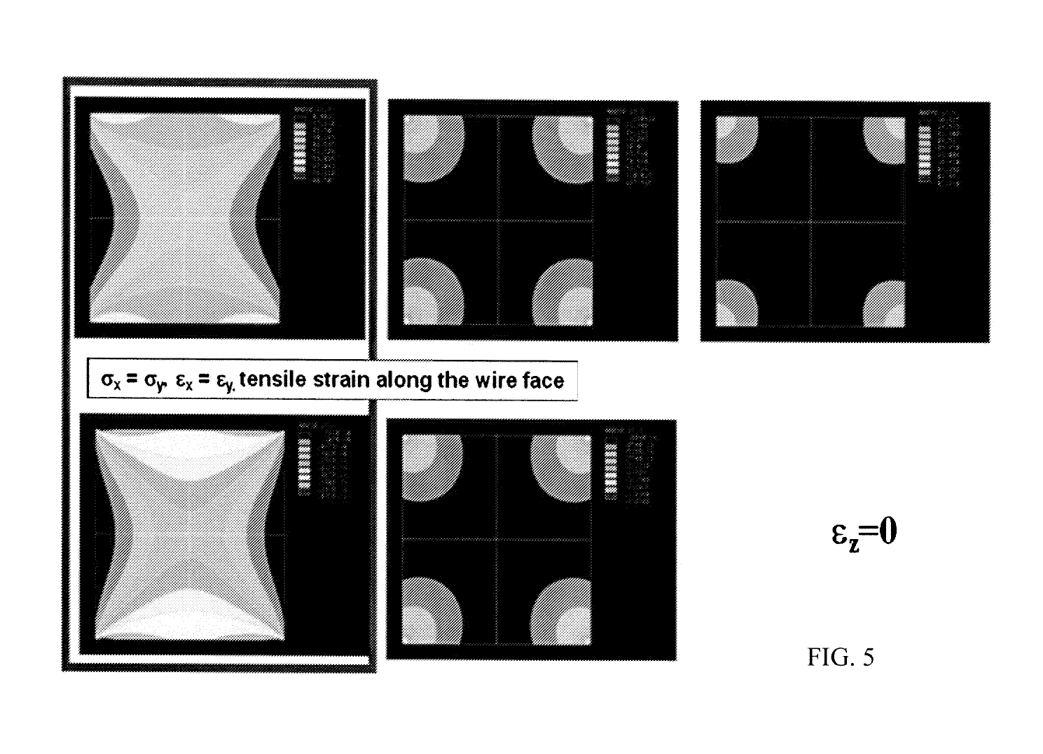

FIG. 5 illustrates graphically the tensile strain along the face of the square 20 nm×20 nm nanowire under a stress simulation. The gate oxide layer is not shown at FIG. 5. FIG. 5 illustrates the stress inside of this square nanowire as caused by a thin compressive film of silicon dioxide when the film has −100 MPa of stress. From FIG. 5 we acquire the a values which are used, along with the piezoelectric coefficients such as those presented at Table 1, to calculate the mobility such as via the equations presented below.

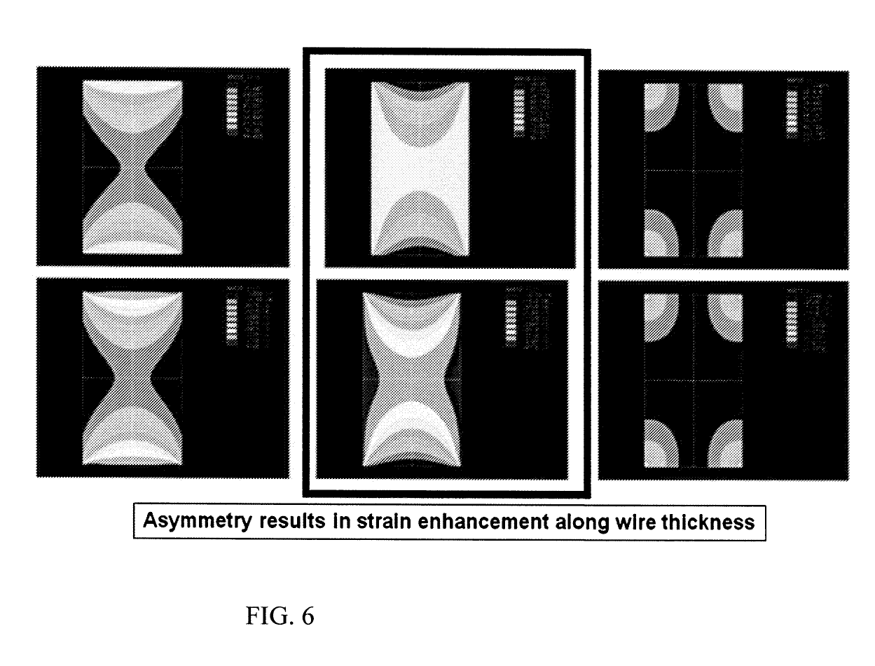

FIG. 6 is similar to FIG. 5 but for a stress simulation on a rectangular nanowire of cross section 12 nm×20 nm. The asymmetrical strain results clearly illustrated there will be reflected in the σ and the δμ/μ values that such a stress simulation yields which influence the resulting mobility, which mobility can then be quantified according to the more generalized equations (1) and (2) below.

Table 1 lists piezoelectric coefficients in the nanostructure of the semiconductor channel 106, for example. In particular, Table 1 shows the bulk piezoelectric coefficients in <110> oriented nanostructure of the semiconductor channel 106 where <110> indicates the Miller Indices as appreciated by a person having ordinary skill in the art. Miller Indices may also be indicated by (1-10), (001), and (110). The symbol π indicates a piezoelectric coefficient and the subscripts L, V, and T indicate axes as described below.

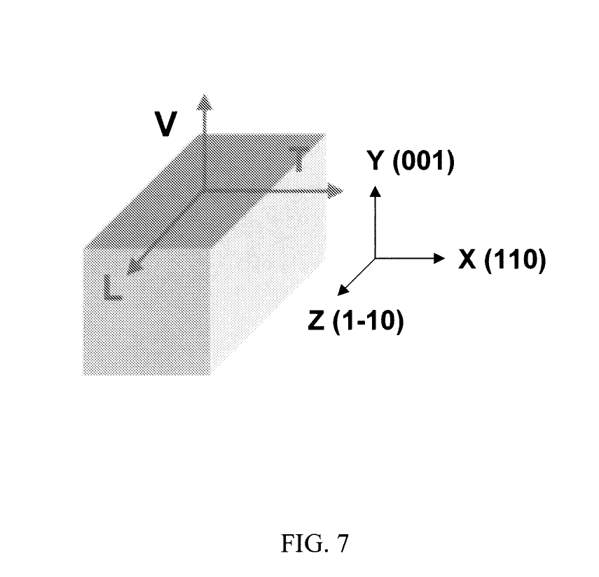

FIG. 7 illustrates the orientation of the relevant directions for the top and bottom nanowire channel surfaces (if the nanowire is substantially a square or a rectangle in cross-section) to determine a mobility delta in top/bottom surfaces of the nanostructure of the semiconductor channel 106, for example. A mobility delta may be represented by:

δμ/μ=−π_{T} σ_{T}−π_{V} σ_{V}−π_{L} σ_{L}=−π_{T} σ_{X-π}_{V} σ_{Y}−π_{L} σ_{Z}, Eq. (1)

where σ represents a stress.

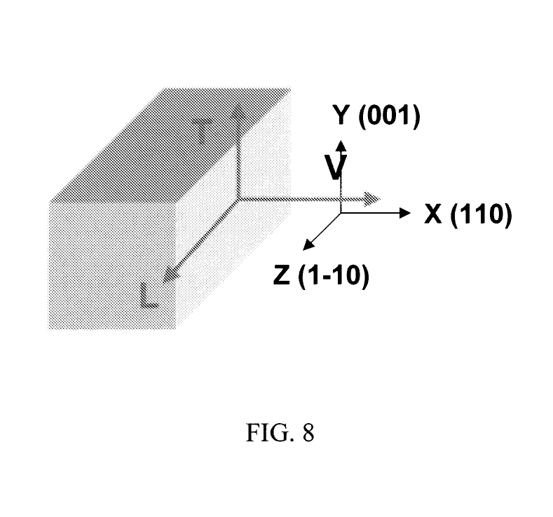

FIG. 8 illustrates the orientation of the relevant directions for the top and bottom nanowire channel surfaces (if the nanowire is substantially a square or a rectangle in cross-section) to determine a mobility delta in left/right surfaces of the nanostructure of the semiconductor channel 106, for example. A mobility delta may be represented by:

δμ/μ=−π_{T} σ_{T}−π_{V} σ_{V}−π_{L} σ_{L}=−π_{T} σ_{Y}−π_{V} σ_{X}−π_{L} σ_{Z}, Eq. (2)

where σ represents a stress. A positive sign of σ may indicate a tensile stress and a negative sign of a may indicate a compressive stress.

The mobility delta observed for a compressive film such as that shown at FIG. 5 may be given by for an nFET:

δμ/μ of 20×20=0.5*(δμ/μ of T/B+δμ/μ of L/R)=−4059, Eq. (3)

for a PFET:

δμ/μ of 20×20=0.5*(δμ/μ of T/B+δμ/μ of L/R)=7603, Eq. (4)

Accordingly, the compressive film, by subjecting a tension in the nanostructure semiconductor channel 106, may be expected to enhance the electric mobility in the pFET and degrade the electric mobility in nFET. This effect may become more pronounced in an nFET of a smaller size while a PFET may not be sensitive to this effect.

The mobility delta observed for a tensile film may be given by for an nFET:

δμ/μ of 20×20=0.5*(δμ/μ of T/B+δμ/μ of L/R)=4059, Eq. (5)

and for a PFET:

δμ/μ of 20×20=0.5*(δμ/μ of T/B+δμ/μ of L/R)=−7603. Eq. (6)

Accordingly, the tensile film, by subjecting a compression in the nanostructure semiconductor channel 106, may be expected to enhance the electric mobility in the nFET and degrade the electric mobility in pFET. This effect may become more pronounced in an nFET of a smaller size while a pFET may not be sensitive to this effect.

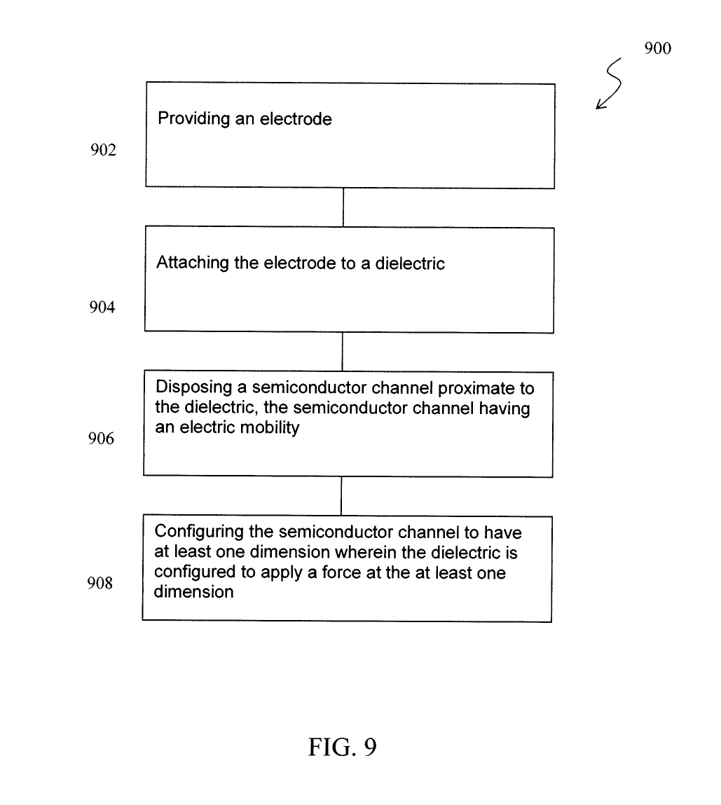

FIG. 9 illustrates an embodiment of a method 900 of the present disclosure. The method 900 may include providing an electrode (block 902), attaching the electrode to a dielectric (block 904), disposing a semiconductor channel proximate to the dielectric, the semiconductor channel having an electric mobility (block 906), and configuring the semiconductor channel to have at least one dimension wherein the dielectric is configured to apply a force at the at least one dimension (block 908).

In the method 900, the providing the electrode may further include providing a gate. In the method 900, the attaching the electrode to the dielectric may further include attaching the electrode to a gate dielectric. In the method 900, the configuring the semiconductor channel may further include providing at least one of a field effect transistor nanostructure n-channel and a field effect transistor nanostructure p-channel.

Another embodiment of the method 900 may include attaching an electrode to a gate, attaching the electrode to a dielectric, disposing a semiconductor channel proximate to the dielectric, the semiconductor channel having an electric mobility, wherein the semiconductor channel may couple a source and a drain, and configuring the semiconductor channel to have at least one dimension wherein the dielectric may be configured to apply a force at the at least one dimension.

In another embodiment of the method 900, the attaching the electrode to the dielectric may further include attaching the electrode to a gate dielectric. In another embodiment of the method 900, the configuring the semiconductor channel may further include configuring at least one of a nanostructure n-channel and a nanostructure p-channel.

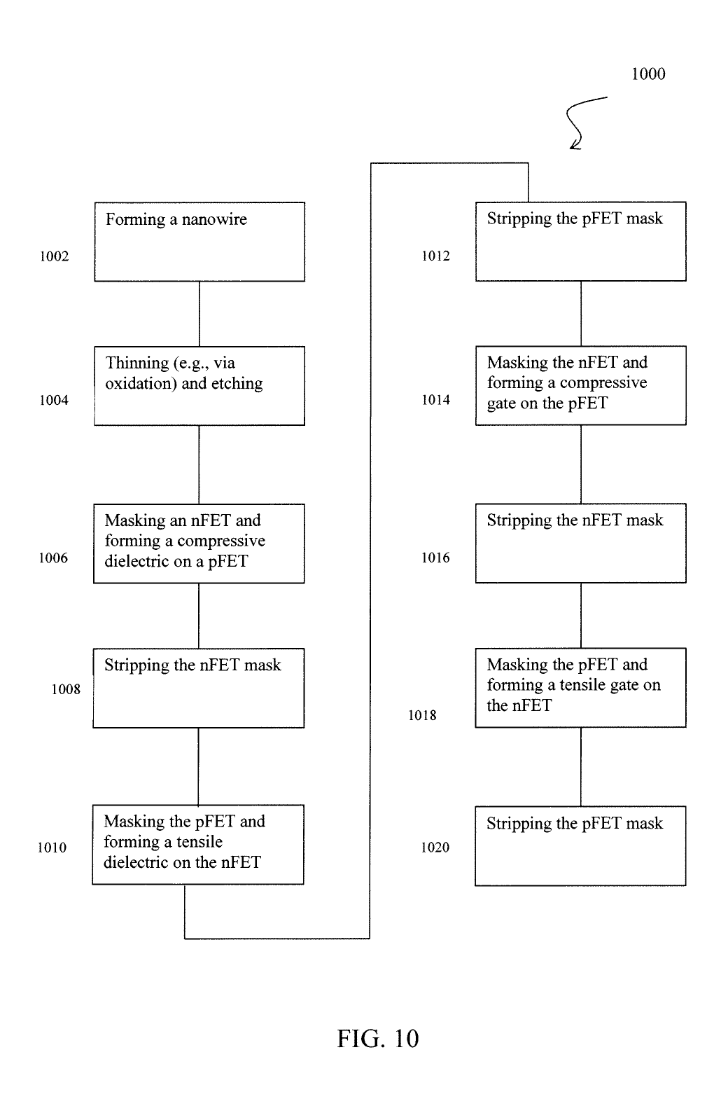

FIG. 10 illustrates an embodiment of a method 1000 of the present disclosure. The method 1000 may include forming a nanowire (block 1002), thinning with oxidation and etching (block 1004), masking an nFET and forming a compressive dielectric, such as a thermal oxidation of about 1 nm thickness or a compressive oxynitride deposit of about 1 nm thickness, on a pFET (block 1006), stripping the nFET mask (block 1008), masking the pFET and forming a tensile dielectric, such as but not limited to by depositing a thickness of about 2 nm of HfO₂ (Hafnium Oxide) or deposit a tensile oxynitride of about 1 nm thickness, on the nFET (block 1010), stripping the pFET mask (block 1012), masking the nFET and forming a compressive gate, such as but not limited to by depositing a compressive polysilicon and etching the gate, on the pFET (block 1014), stripping the nFET mask (block 1016), masking the PFET and forming a tensile gate, such as but not limited to by depositing materials like TaN, TiN, or tensile polysilicon and etching the gate, on the nFET (block 1018), and stripping the pFET mask (block 1020).

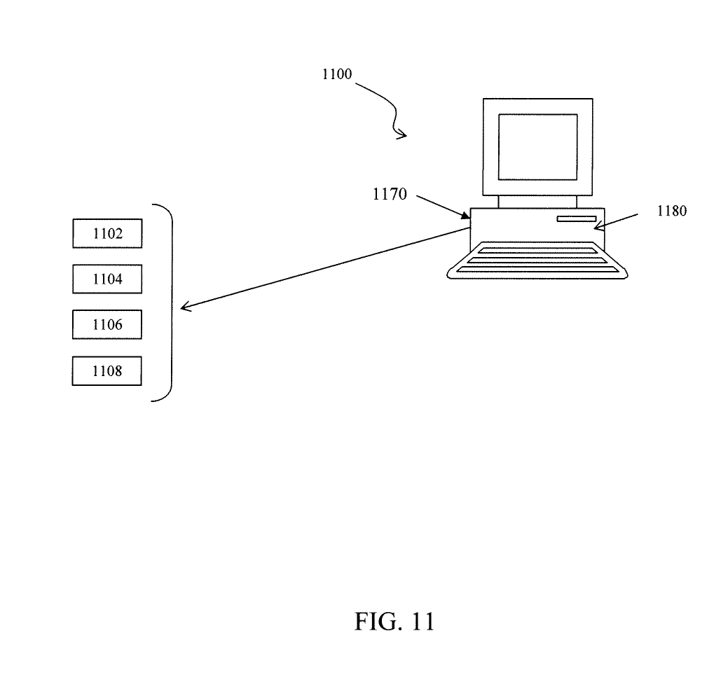

FIG. 11 illustrates a system 1100 including a computer program product 1180 having computer-executable instructions to implement the method of FIG. 10. The system 110 may include a computer 1170 having the computer program product 1180. The computer program product 1180 may have computer-executable instructions for: attaching an electrode to a gate (block 1102), attaching the electrode to a dielectric (block 1104), disposing a semiconductor channel proximate to the dielectric, the semiconductor channel having an electric mobility, wherein the semiconductor channel couples a source and a drain (block 1106), and configuring the semiconductor channel to have at least one dimension wherein the dielectric is configured to apply a force at the at least one dimension (block 1108).

The terminology used herein is for the purpose or describing particular embodiments only and is not intended to be limiting or the invention. As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. An embodiment was chosen and described in order to best explain the principles of the invention and the practical application, and to enable others of ordinary skill in the art to understand the invention for various embodiments with various modifications as are suited to the particular use contemplated.

As a person having ordinary skill in the art would appreciate, the elements or blocks of the methods described could take place at the same time or in an order different from the described order.

It should be emphasized that the above-described embodiments are merely some possible examples of implementation, set forth for a clear understanding of the principles of the disclosure. Many variations and modifications may be made to the above-described embodiments of the invention without departing substantially from the principles of the invention. All such modifications and variations are intended to be included herein within the scope of this disclosure and the present invention and protected by the following claims.

What is claimed is:

1. A semiconductor, comprising:
a dielectric;
an electrode attached to the dielectric;
a semiconductor channel disposed proximate to the dielectric, wherein the semiconductor channel has an electric mobility and is configured to have at least one dimension; and
wherein the dielectric is configured to apply a force at the at least one dimension.

2. The semiconductor of claim 1, wherein the electrode is a gate.

3. The semiconductor of claim 1, wherein the dielectric is a gate dielectric.

4. The semiconductor of claim 1, wherein the semiconductor channel is at least one of a field effect transistor nanostructure n-channel and a field effect transistor nanostructure p-channel.

5. The semiconductor of claim 1, wherein the electric mobility is one of an electron mobility and a hole mobility.

6. The semiconductor of claim 1, wherein a thickness of the dielectric is configured to change the electric mobility.

7. The semiconductor of claim 1, wherein the dielectric is configured to be compressive for a PFET (p-channel field effect transistor).

8. The semiconductor of claim 7, wherein the dielectric is attached to a compressive gate coupled to the pFET.

9. The semiconductor of claim 1, wherein the dielectric is configured to be tensile for an nFET (n-channel field effect transistor).

10. The semiconductor of claim 9, wherein the dielectric is attached to a tensile gate coupled to the nFET.

11. A field effect transistor (FET), comprising:
an electrode attached to a gate and to a dielectric;
a semiconductor channel coupling a source and a drain, the semiconductor channel having an electric mobility and configured to have at least one dimension;
wherein the dielectric is configured to apply a force at the at least one dimension.

12. The FET of claim 11, wherein the dielectric is a gate dielectric.

13. The FET of claim 1 1, wherein the semiconductor channel is at least one of a nanostructure n-channel and a nanostructure p-channel.

14. The FET of claim 11, wherein the electric mobility is one of an electron mobility and a hole mobility.

15. The FET of claim 11, wherein a thickness of the dielectric is configured to change the electric mobility.

16. The FET of claim 11, wherein the dielectric is configured to be compressive for a pFET and the dielectric is attached to a compressive gate coupled to the PFET.

17. The FET of claim 11, wherein the dielectric is configured to be tensile for an nFET and the dielectric is attached to a tensile gate coupled to the nFET.

18. A method, comprising:
providing an electrode;
attaching the electrode to a dielectric;
disposing a semiconductor channel proximate to the dielectric, the semiconductor channel having an electric mobility; and
configuring the semiconductor channel to have at least one dimension wherein the dielectric is configured to apply a force at the at least one dimension.

19. The method of claim 18, wherein the providing an electrode further comprises providing a gate.

20. The method of claim 18, wherein the attaching the electrode to the dielectric further comprises attaching the electrode to a gate dielectric.

21. The method of claim 18, wherein the configuring the semiconductor channel further comprises providing at least one of a field effect transistor nanostructure n-channel and a field effect transistor nanostructure p-channel.

22. A method, comprising:
attaching an electrode to a gate;
attaching the electrode to a dielectric;
disposing a semiconductor channel proximate to the dielectric, the semiconductor channel having an electric mobility, wherein the semiconductor channel couples a source and a drain; and
configuring the semiconductor channel to have at least one dimension wherein the dielectric is configured to apply a force at the at least one dimension.

23. The method of claim 22, wherein the attaching the electrode to the dielectric further comprises attaching the electrode to a gate dielectric.

24. The method of claim 22, wherein the configuring the semiconductor channel further comprises configuring at least one of a nanostructure n-channel and a nanostructure p-channel.

25. A computer program product having computer-executable instructions for:
attaching an electrode to a gate;
attaching the electrode to a dielectric;
disposing a semiconductor channel proximate to the dielectric, the semiconductor channel having an electric mobility, wherein the semiconductor channel couples a source and a drain; and
configuring the semiconductor channel to have at least one dimension wherein the dielectric is configured to apply a force at the at least one dimension.
